(19) United States
(12) Patent Application Publication
(10) Pub. No.: US 2026/0341596 A1
(43) Pub. Date: Oct. 29, 2026

(54) CAPACITOR MODULE AND INVERTER MODULE

(71) Applicant: LG INNOTEK CO., LTD., Seoul (KR)

(72) Inventors: Sung June PARK, Seoul (KR); Tae Bok JUNG, Seoul (KR)

(73) Assignee: LG INNOTEK CO., LTD., Seoul (KR)

(21) Appl. No.: 19/107,419

(22) PCT Filed: Aug. 25, 2023
(86) PCT No.: PCT/KR2023/012678

§ 371 Date: Feb. 27, 2025

(30) Foreign Application Priority Data
Aug. 30, 2022 (KR) 10-2022-0109518

(51) Int. Cl. H01G 2/10; H01F 27/02; H01F 37/00; H01G 2/06; H02M 7/00; H05K 7/14; H05K 7/20

(52) U.S. Cl. CPC H01G 2/10; H01F 27/022; H01F 37/005; H01G 2/06; H05K 7/1432; H05K 7/209; H02M 7/003

(57) ABSTRACT

A capacitor module according to an embodiment of the present invention comprises: a housing including an accommodation groove in which a capacitor is disposed; a substrate disposed above the accommodation groove; and at least one capacitor mounted to the one surface and accommodated in the accommodation groove.

### TECHNICAL FIELD

The present invention relates to a capacitor module and an inverter module including the same, and more specifically, to a capacitor module in which a link capacitor is formed as a separate module, and an inverter module including the same.

### BACKGROUND ART

Photovoltaic power generation is an eco-friendly energy generation method that is widely used as a replacement for existing chemical power generation or nuclear power generation. Photovoltaic power generation can be either a standalone type where a battery is connected to a converter or a connected type where it is connected to a power grid. Standalone power generation is generally composed of solar cells, storage batteries, and power conversion devices, while a power grid-connected system is configured to be connected to a commercial power source so that power can be exchanged with the load grid line.

The electricity generated by solar panels cannot be used directly in homes or buildings, so it is converted into usable electricity through a power conversion device such as an inverter.

In the inverter, the link capacitor component is large in size and has a large mounting quantity, so it occupies a large area on the PCB, which leads to a shortage of PCB mounting space, and there is a problem that the product size increases due to the increase in PCB size. In addition, the mounting space of the PCBs that are stacked in two layers on the main PCB is also insufficient, and there is a problem that the shape of the stacked PCBs is restricted, and accordingly, there is a problem that there is a restriction on the mounting location of the connector between the stacked PCBs and the main PCB.

### DETAILED DESCRIPTION OF THE INVENTION

### Technical Subject

The technical problem to be solved by the present invention is to provide a capacitor module in which a link capacitor is formed as a separate module and an inverter module including the same.

### Technical Solution

In order to solve the above technical problem, a capacitor module according to one embodiment of the present invention comprises: a housing including an accommodation groove in which a capacitor is disposed; a substrate being disposed above the accommodation groove; and at least one capacitor being mounted on one surface and accommodated in the accommodation groove.

In addition, a plurality of first connectors being electrically connected to the capacitors may be disposed in the other surface of the substrate.

In addition, the capacitor may include a link capacitor.

In addition, it may include a plurality of heat dissipation fins being extended from an outer surface the accommodation groove.

In addition, the accommodation groove may include: a base; a first side wall and a second side wall being extended from the base and facing each other; and a third side wall and a fourth side wall perpendicular to the first side wall and the second side wall and facing each other.

In addition, the accommodation groove may include: a first accommodation groove in which the capacitor is accommodated therein; a second accommodation groove in which an inductor is disposed therein and is spaced apart from the first accommodation groove; and at least one inductor being electrically connected to one surface of the substrate and accommodated in the second accommodation groove.

In addition, the second accommodation groove may include a base; and a fifth side wall being extended from the base and having a circular shape.

In addition, the inductor includes two inductors, and the two inductors are stacked in two layers in a depthwise direction of the second accommodation groove and can be connected to one surface of the substrate by a wire.

In addition, a plurality of second connectors being electrically connected to the inductor may be disposed in the other surface of the substrate.

In addition, a capacitor or inductor may be molded into the accommodation groove.

In order to solve the above technical problem, an inverter module according to an embodiment of the present invention comprises: a first housing including a base including a first hole and having a main substrate disposed therein; a cover covering the first housing; a heat sink including a plurality of heat dissipation fins corresponding to the first hole and being coupled to the first housing and extended outward; and a capacitor module being disposed in a portion of an outer surface of the heat sink, wherein the capacitor module includes a second housing including an accommodation groove in which a capacitor is disposed therein; a first substrate being disposed at an upper portion of the accommodation groove; and at least one capacitor mounted on one surface of the first substrate and accommodated in the accommodation groove.

In addition, a plurality of first connectors being electrically connected to the capacitor is disposed on the other surface of the first substrate, wherein the heat sink may include a through hole in a region corresponding to the plurality of first connectors.

In addition, the plurality of first connectors may pass through the through hole to be connected to the main substrate.

In addition, the first connector may include at least one among an SMD spacer, a wire connector, and a busbar terminal stand.

In addition, the main substrate may include a first main substrate and a second main substrate being stacked to be spaced apart from the first main substrate.

In addition, the accommodation groove of the capacitor module includes: a first accommodation groove in which the capacitor is accommodated; a second accommodation groove in which an inductor is disposed; and at least one first inductor being electrically connected to one surface of the substrate and accommodated in the second accommodation groove.

In addition, the first inductor includes two of the first inductors, wherein the two of the first inductors are stacked in two layers in a depthwise direction to be connected to one surface of the first substrate through a wire.

In addition, it includes an inductor module being disposed in other portion of the outer surface of the heat sink, wherein the inductor module may include: a third housing including a third accommodation groove in which a second inductor is disposed; and at least one second inductor accommodated in the third accommodation groove.

### Advantageous Effects

According to embodiments of the present invention, the Main PCB mounting area can be secured to the maximum extent possible to minimize the product size. In addition, a link capacitor can be positioned externally as a separate module to enable efficient heat dissipation. Furthermore, by separating and fastening it as a separate module, the weight of the link capacitor can be stably supported.

### BRIEF DESCRIPTION OF DRAWINGS

FIG. 1 is a perspective view of a capacitor module according to an embodiment of the present invention.

FIG. 2 is an exploded perspective view of a capacitor module according to an embodiment of the present invention.

FIGS. 3 to 5 are diagrams for describing each configuration of a capacitor module according to an embodiment of the present invention.

FIG. 6 is a perspective view of an inverter module according to an embodiment of the present invention.

FIG. 7 is a cross-sectional view of an inverter module according to an embodiment of the present invention.

FIGS. 8 to 16 are diagrams for explaining each configuration of an inverter module according to an embodiment of the present invention.

### [BEST MODE]

Hereinafter, preferred embodiments of the present invention will be described in detail with reference to the accompanying drawings.

However, the technical idea of the present invention is not limited to some embodiments to be described, but may be implemented in various forms, and inside the scope of the technical idea of the present invention, one or more of the constituent elements may be selectively combined or substituted between embodiments.

In addition, the terms (including technical and scientific terms) used in the embodiments of the present invention, unless explicitly defined and described, can be interpreted as a meaning that can be generally understood by a person skilled in the art, and commonly used terms such as terms defined in the dictionary may be interpreted in consideration of the meaning of the context of the related technology.

In addition, terms used in the present specification are for describing embodiments and are not intended to limit the present invention.

In the present specification, the singular form may include the plural form unless specifically stated in the phrase, and when described as “at least one (or more than one) of A and B and C”, it may include one or more of all combinations that can be combined with A, B, and C.

In addition, in describing the components of the embodiment of the present invention, terms such as first, second, A, B, (a), and (b) may be used. These terms are merely intended to distinguish the components from other components, and the terms do not limit the nature, order or sequence of the components.

And, when a component is described as being ‘connected’, ‘coupled’ or ‘interconnected’ to another component, the component is not only directly connected, coupled or interconnected to the other component, but may also include cases of being ‘connected’, ‘coupled’, or ‘interconnected’ due that another component between that other components.

In addition, when described as being formed or disposed in “on (above)” or “below (under)” of each component, “on (above)” or “below (under)” means that it includes not only the case where the two components are directly in contact with, but also the case where one or more other components are formed or disposed between the two components. In addition, when expressed as “on (above)” or “below (under)”, the meaning of not only an upward direction but also a downward direction with respect to one component may be included.

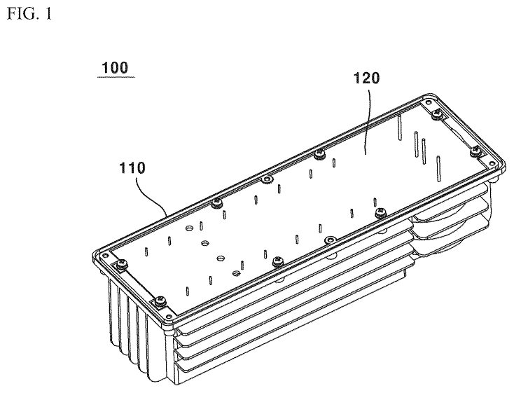

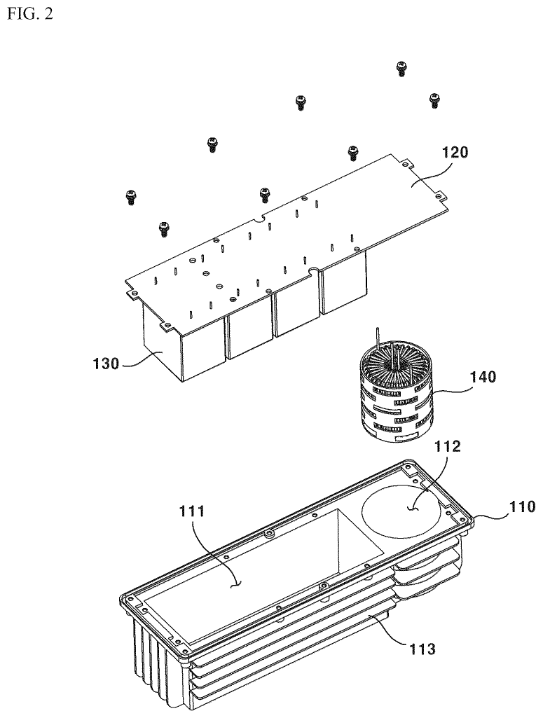

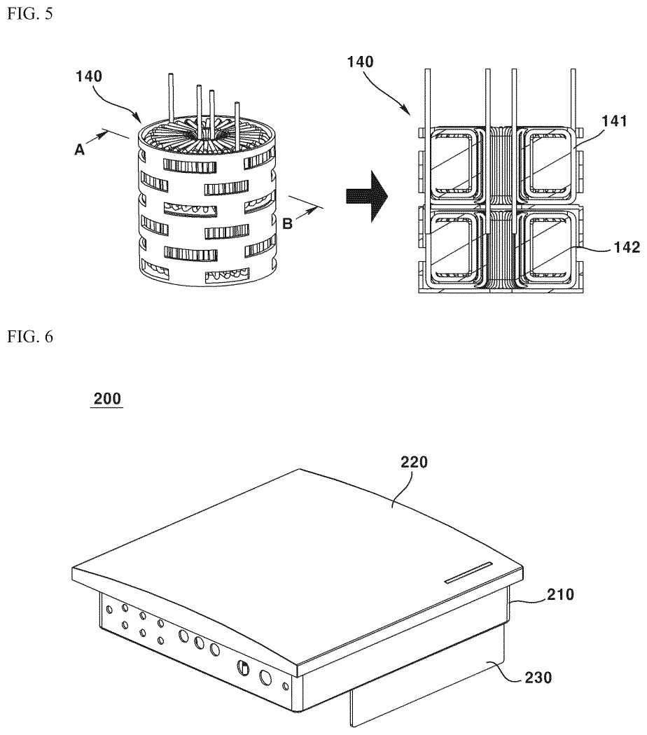

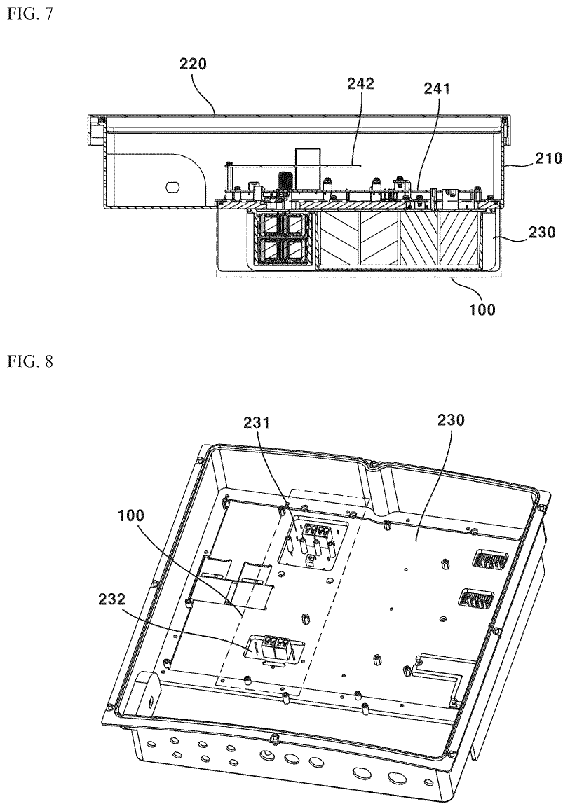

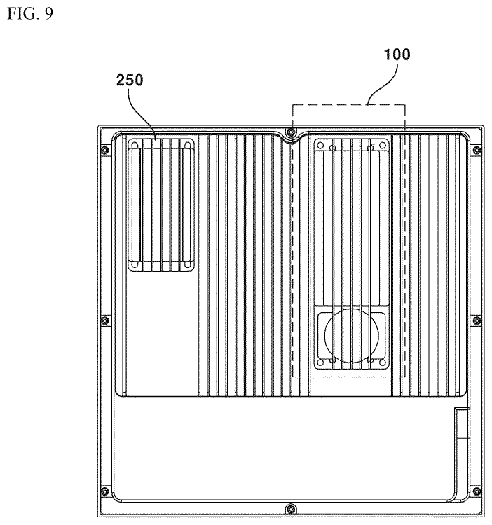

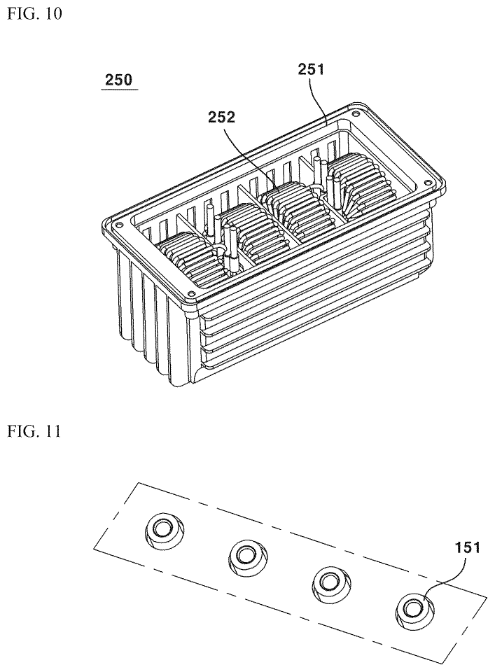

FIG. 1 is a perspective view of a capacitor module according to an embodiment of the present invention; FIG. 2 is an exploded perspective view of a capacitor module according to an embodiment of the present invention; FIGS. 3 to 5 are diagrams for describing each configuration of a capacitor module according to an embodiment of the present invention; FIG. 6 is a perspective view of an inverter module according to an embodiment of the present invention; FIG. 7 is a cross-sectional view of an inverter module according to an embodiment of the present invention; and FIGS. 8 to 16 are diagrams for explaining each configuration of an inverter module according to an embodiment of the present invention.

The capacitor module 100 according to an embodiment of the present invention includes a housing 110, a substrate 120, and a capacitor 130.

The housing 110 includes an accommodation groove in which a capacitor 130 is disposed, wherein the substrate 120 is disposed above the accommodation groove, and wherein the capacitor 130 is mounted on one surface of the substrate 120 and is accommodated in the accommodation groove.

The housing 110 includes an accommodation groove in which at least one capacitor 130 is disposed inside. The accommodation groove inverter module 200 may be formed in a shape corresponding to the shape of the capacitor 130 so as to accommodate the capacitor 130 disposed inside. The accommodation groove may be configured with a base in which an inductor is disposed and side walls forming an internal space. The internal space of the accommodation groove may have a hexahedral shape, a cylindrical shape, or a polyhedral shape. The accommodation groove may include a base, a first side wall and a second side wall being extended from the base and facing each other, and a third side wall and a fourth side wall perpendicular to the first side wall and the second side wall and facing each other. A hexahedral shape may be formed through the base and the four side walls. It is natural that the shape of the accommodation groove may be formed in various shapes depending on the shape or size of a component being accommodated inside.

A capacitor 130 or an inductor 140 may be accommodated in the accommodation groove. The accommodation groove may include a first accommodation groove 111 in which the capacitor 130 is disposed and a second accommodation groove 112 in which the inductor 140 is disposed.

The first accommodation groove 111 and the second accommodation groove 112 may have different areas or shapes from each other. A capacitor 130 may be accommodated inside the first accommodation groove, and an inductor 140 may be accommodated inside the second accommodation groove 112. Alternatively, components mounted together with the inductor 140 may be accommodated. The size of the first accommodation groove 111 may be larger than the second accommodation groove 112. The first accommodation groove 111 and the second accommodation groove 112 may have different lengths from each other in a direction perpendicular to the first and second directions. A partition wall is formed between the first accommodation groove 111 and the second accommodation groove 112 so that they can be independently separated from each other. This can prevent them from being electrically connected to each other, and also, it can prevent the heat generated from each from affecting each other.

As described above, the first accommodation groove 111 may include a base corresponding to the capacitor 130 to be accommodated, first and second sidewalls being extended from the base and facing each other, and the third sidewall and the fourth sidewall perpendicular to the first sidewall and second sidewall and facing each other.

The capacitor 130 may include a link capacitor. The link capacitor is a capacitor being connected to the DC-Link, and is a capacitor for stabilizing the voltage of the DC-Link by removing or minimizing noise. The capacitor 130 may have a rectangular parallelepiped shape, and a plurality of capacitors may be connected in parallel to each other to form required capacitor capacity. Alternatively, it is obvious that the capacitor 130 may be connected in series or in series and parallel. Since the size of the component is large and the number of mounting portions of the capacitor 130 is large, the size of a device including the capacitor 130 may be minimized by forming a separate module, and a space in which the capacitor 130 is mounted may be utilized.

The capacitor 130 is disposed inside the first accommodation groove 111. The capacitor 130 may include at least one capacitor, and may include a plurality of capacitors. For example, when the capacitor module 100 is a capacitor module applied to a three-phase inverter module, four capacitors may be included, and the four capacitors may be disposed in a line and disposed on the first accommodation groove 111. A single-phase inverter module may include 10 or more capacitors.

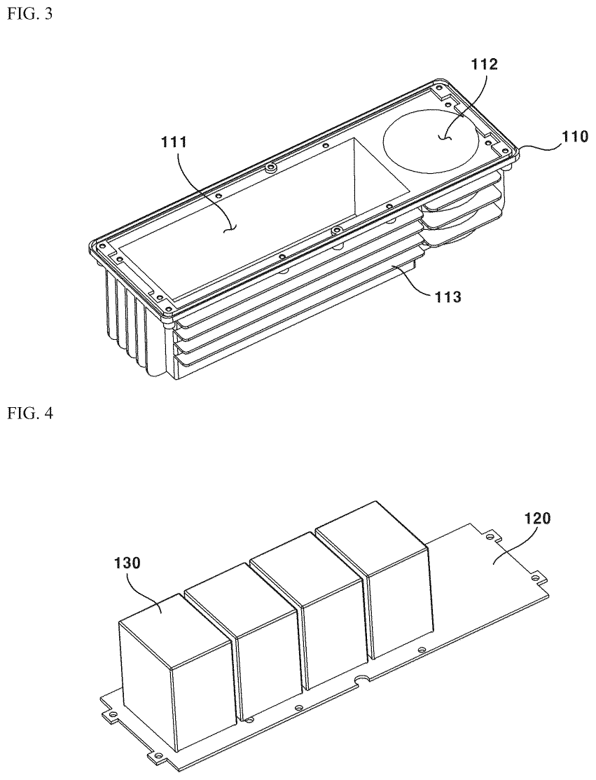

The capacitor 130 may be mounted on one surface of the substrate 120. As shown in FIGS. 2 and 4, the capacitor 130 may be mounted on one surface of the substrate 120 facing the housing 110. In this case, a plurality of holes are formed in the substrate 120, a plurality of connection pins are formed in the capacitor 130, and the connection pins penetrate and are soldered to the plurality of holes formed in the substrate 120, thereby being mounted on one surface of the substrate 120. The capacitor 130 may be electrically connected to the substrate 120, and a plurality of first connectors electrically connected to the capacitor 130 may be disposed on the other surface of the substrate 120. The connection pins of the capacitor 130 and the first connector may be electrically connected through the substrate 120.

The second accommodation groove 112 may include a base, and a fifth sidewall being extended from the base, corresponding to the inductor 140 to be accommodated. Alternatively, a base, first to fourth sidewalls, corresponding to the first accommodation groove, may be included. This may vary according to the shape of the inductor 140 and the arrangement direction of the inductor 140 when a plurality of inductors 140 is included.

The inductor 140 includes two inductors 141 and 142, and the two inductors may be stacked in two layers in a depthwise direction of the second accommodation groove. At this time, the two inductors 141 and 142 may be stacked to be insulated from each other. To be disposed in the capacitor module 100 together with the capacitor 130, the inductor 140 may be stacked. When the size of the capacitor 130 is larger than that of the inductor 140, and when the inductor 140 is disposed in line with the capacitor 130, a space in which the inductor 140 is disposed may be insufficient. To solve this problem, the inductor 140 may be stacked in a depthwise direction of the second accommodation groove 112 perpendicular to the arrangement direction of the capacitor 130, and thus space may be efficiently utilized.

The inductor 140 may be formed by winding a coil in a circular shape, and may be surrounded by a bobbin including a hole therein. At this time, the inductor 140 may be connected to one surface of the substrate 120 through a wire drawn out to the hole. A plurality of second connectors electrically connected to the inductor 140 may be disposed on the other surface of the substrate 120. The wire of the inductor inverter module 200 and the second connector may be electrically connected through the substrate 120.

The inductor 140 is a device formed by a coil, and the inductor 140 is relatively larger than other devices and generates more heat than other devices when performing power conversion. The inductor 140 may be an inductor 140 configuring a DC-DC converter. The inductor 140 may be disposed on the second accommodation groove 112. The inductor 140 generates a large amount of heat, and the heat generated by the inductor 140 may affect not only the inductor itself but also other devices affected by the heat, and thus, the power conversion function may be deteriorated or a failure may occur. Therefore, it is necessary to perform heat dissipation by discharging heat of the inductor 140 to the outside.

For heat dissipation of the capacitor 130 and the inductor 140, the capacitor 130 may be mounted and molded in the first accommodation groove 111, and the inductor 140 may be accommodated and molded in the second accommodation groove 112. After placing the capacitor 130 and the inductor 140 on the accommodation groove, molding is performed to increase the thermal conductivity. Molding is a process of filling and solidifying a liquid material in a frame having a predetermined shape, and heat generated in the capacitor 130 or the inductor 140 is transferred to the housing 110 along the molded material and discharged to the outside through the housing 110 to increase a heat dissipation effect. Since the In addition, the inductor 140 is disposed on the second accommodation groove 112 and fixed through molding, the inductor 140 may be fixed to the inside of the housing 110 without a separate coupling member for fixing the inductor 140.

The housing 110 may include a plurality of heat dissipation fin inverter modules 200 being extended from an outer surface of the accommodation groove. The heat dissipation fin inverter module 200 may include first to third heat dissipation fins being extended from the housing 110. The first heat dissipation fin may be extended in a first direction, which is a downward direction, from the base of the housing 110, the second heat dissipation fin may be extended in a second direction perpendicular to the first direction, and the third heat dissipation fin may be extended in a direction perpendicular to the first direction and opposite to the second direction.

The first heat dissipation fin is extended in a first direction, which is a lower direction, from the base of the housing 110. Here, the first direction may be a lower direction of the housing 110. It may be extended in a first direction from a rear surface, which is an outer surface of the base. Heat generated by the capacitor 130 or the inductor 140 may be heat-conducting in an extending direction of the first heat dissipation fin to be discharged to the outside. The first heat dissipation fin may be extended in a first direction from an outer surface of the base, and may be extended in a third direction, which is perpendicular to the first direction and the second direction, from an outer surface of the first sidewall, and may be integrally formed. The first heat dissipation fin may not only be extended in a first direction, which is a lower direction of the base, but may also be formed to be extended in a third direction, which is perpendicular to the first direction and the second direction, as shown in FIG. 3. Alternatively, it may be extended only in one of the first direction and the third direction, from an outer surface of the first sidewall. Heat generated by the capacitance or inductor 140 is not discharged only in a first direction, but is also discharged in a third direction or an opposite direction to a third direction, thereby increasing a heat dissipation effect.

The first heat dissipation fin may include a plurality of heat dissipation fins being spaced apart from each other at predetermined intervals in the second direction. The direction in which the first heat dissipation fin is disposed may vary depending on the heat conduction direction. For example, the first heat dissipation fin may be formed to have a plate shape in the third direction, and may include a plurality of heat dissipation fins spaced apart from each other at predetermined intervals in the second direction. The interval between adjacent heat dissipation fins may be set in consideration of the efficiency of heat dissipation. At this time, each heat dissipation fin is a heat sink, and may be formed as a thin plate in a structure that performs heat dissipation and may be formed to be spaced apart from each other.

The second heat dissipation fin may be extended in a second direction perpendicular to the first direction, and the third heat dissipation fin may be extended in an opposite direction of the first direction and perpendicular to the second direction. The second heat dissipation fin may be extended from an outer surface of the third sidewall, and the third heat dissipation fin may be extended from an outer surface of the fourth sidewall. The second heat dissipation fin and the third heat dissipation fin may include a plurality of heat dissipation fins being spaced apart from each other at predetermined intervals in the first direction. A detailed description of the shape or interval of the plurality of heat dissipation fins corresponds to a detailed description of the first heat dissipation fin. Each of the first heat dissipation fin, the second heat dissipation fin, and the third heat dissipation fin has a plate shape being erected in a third direction, which is the same direction, and when coupled to the inverter module, a third direction becomes an up and down direction, so that heat transfer may be smoothly performed.

Due to the extension in the first direction, the third direction, and the opposite direction of the third direction of the first heat dissipation fin, the second direction of the second heat dissipation fin, and the opposite direction of the second direction of the third heat dissipation fin, heat can be transferred in five directions, so that heat dissipation is possible in five directions except for the upper surface that must be coupled with the inverter module 200, and through this, the effect of heat dissipation can be enhanced.

A capacitor module 100 according to an embodiment of the present invention may be coupled to an inverter module 200. An inverter module 200 according to an embodiment of the present invention is composed of a first housing 210, a cover 220, a heat sink 230, main substrates 241, and 242, a capacitor module 100, as shown in FIG. 6, and may include an inductor module 250. A detailed description of the capacitor module 100 configuring the inverter module 200 corresponds to the detailed description of the capacitor module 100 of FIGS. 1 to 5, and thus, any overlapping description will be omitted below.

The inverter module 200 may be a PV inverter module. The PV inverter module is a device that receives power from a PV panel or PV MLPE and converts it into power that can be used in a home or building, and receives DC power such as a PV converter, converts it into AC power, and outputs it. At this time, the DC power is transmitted to the inverter driving unit through a wire, and the inverter driving unit can convert the power, and transmit the converted power to a load again through a wire. The inverter driving unit may include a power conversion element and a switching element or MCU that controls the power conversion element. The power conversion element may include a passive element such as an inductor or a capacitor, and may include a switching element being implemented as a FET or a diode, and may include an MCU that controls the switching element. In addition, various elements for converting power may be included, or elements for implementing functions other than power conversion may be included.

The first housing 210 includes a base including a first hole, and a main substrate is disposed inside. The cover 220 can cover the first housing 210. At this time, the first housing 210 may form an internal space, and the cover 220 may cover it, or the cover 220 may form an internal space and cover the first housing 210. In addition, it may be formed in various forms that form an internal space.

Other components other than those being disposed in the capacitor module 100) or the inductor module 250 may be disposed on the main substrate. The main substrate may include a printed circuit board (PCB). It is to be understood that various types of substrates other than the printed circuit board may be included. The main substrate 241 may be formed as a single layer or multiple layers. The main substrate may include a first main substrate 241 and a second main substrate 242 being spaced apart from the first main substrate 241 and stacked. Inverter module capacity and function of the inverter module 200 are diversified, a larger number of components may be disposed, or the main substrate may be formed as a multiple layer in the process of reducing the size of the inverter module 200. At this time, a capacitor 130 with a large component size may interfere with stacking the substrate, but by using a separate capacitor module 100 and positioning it outside rather than inside the first housing 210, the space for stacking the main substrate can be secured.

The heat sink 230 is coupled to the first housing 210 and includes a plurality of heat dissipation fins being extended outwardly, corresponding to the first hole of the first housing 210. A main substrate 241 is disposed in the inside of the first hole, so that heat being generated from the main substrate 241 is transferred to the heat sink 230 and discharged to the outside through the plurality of heat dissipation fins.

The capacitor module 100 is disposed in a lower portion of the first housing 210, that is, in a portion of the outer surface of the heat sink 230. The capacitor module 100 includes a second housing 110 including an accommodation groove in which a capacitor 130 is disposed inside, a first substrate 120 being disposed at an upper portion of the accommodation groove, and at least one capacitor 130 being mounted on one surface of the first substrate 120 and accommodated in the accommodation groove.

The accommodation groove of the capacitor module 100 may include a first accommodation groove 111 in which the capacitor 130 is accommodated, and a second accommodation groove 112 in which an inductor 140 is disposed and spaced apart from the first accommodation groove 111, and may include at least one first inductor 140 being electrically connected to one surface of the substrate 120 and accommodated in the second accommodation groove.

In this case, the first inductor 140 includes two first inductors 141 and 142, and the two first inductors 141 and 142 may be stacked in two layers in a depthwise direction of the second accommodation groove and connected to one surface of the first substrate 120 by a wire.

The first substrate 120 may include a plurality of first connectors electrically connected to the capacitor 130 and a plurality of second connectors electrically connected to the first inductors 141 and 142 on the other surface thereof.

At this time, the heat sink may include a through hole in a region corresponding to the first connector or the second connector, and the first connector or the second connector may be connected to the main board through the through hole.

The capacitor module 100 may include a first substrate 120 separate from the main substrate 241, and may connect the capacitor 130 or the inductor 140 to the main substrate 241 through the first substrate 120.

Even if the capacitor module 100 is disposed at a lower portion of the region of the heat sink 230 and its position is fixed, as shown in FIGS. 7 to 9, since the capacitor module 100 is connected to the main substrate 241 through the first connector or the second connector of the first substrate 120, the connection position of the capacitor 130 or the inductor 140 with the main substrate 241 is not limited and may be changed to various positions. Accordingly, the degree of freedom in design may be increased even in the arrangement of elements being disposed in the main substrate 241. Since the capacitor module 100 is coupled from the outside of the heat sink 230, a space inside the housing may be secured, and thus a sufficient space for implementing the main substrate 241 in a multilayer manner may be secured.

By separating and fastening the capacitor module 100 into a separate module, heat dissipation is possible outside the housing, efficient heat dissipation is possible, and stable support for the weight of the capacitor is possible.

The inductor module 250 may be disposed in other partial region of an outer surface of the heat sink 230. The inductor module 250 may be disposed to be spaced apart from the capacitor module 100, and heat being generated by being spaced apart from one another may not be affected. The inductor module 250 may include a third housing 251 including a third accommodation groove in which the second inductor 252 is disposed, and at least one second inductor 252 being accommodated in the third accommodation groove. The inductor module 250 may include an inverter side inductor, and the second inductor 252 being disposed in the inductor module 250 is an inductor different from the inductor 140 being disposed in the second accommodation groove 112 of the capacitor module 100. At this time, the second inductor 252 includes a plurality of second inductors, and the plurality of second inductors 252 may be disposed in a line instead of being stacked and disposed in the inductor module 250. The inductor module 250 may have a separate heat dissipation structure. It may include first to third heat dissipation fins, together with a capacitor module 100, to allow heat dissipation in three different directions. Efficient heat dissipation is possible by arranging the second inductor 252 outside the first housing 210.

The capacitor module 100 or the inductor module 250 may be coupled to the heat sink 230 through a fastening portion, and the heat sink 230 may be coupled to the first housing 210 through a fastening portion. The capacitor module 100 or the inductor module 250 may be coupled to the heat sink 230 and the first housing 210 through a fastening portion. At this time, the bolt may be coupled. To this end, a coupling hole may be formed in a surface of the capacitor module 100 or the inductor module 250 in contact with the heat sink 230, and a coupling groove may be formed at a position of the heat sink 230 corresponding to the coupling hole. The coupling groove is not opened for waterproofing, and is formed as a groove having a thread, and may be coupled to a bolt being inserted through the coupling hole of the inductor heat dissipation module inverter module 200. For waterproofing and dustproofing at the time of coupling, a sealing structure such as a sealing member may be formed.

As described above, the first substrate 120 of the capacitor module 100 is connected through the through hole of the main substrate 241 and the heat sink 230, and at this time, the first connector or the second connector of the capacitor module 100 may include at least one among an SMD spacer, a wire connector, and a busbar terminal stand. As shown in FIGS. 11 and 12, the first connector or the second connector may be formed as an SMD spacer 151. The connection between the first substrate 120 and the main substrate 241 is supported by the SMD spacer 151 having an empty space formed therein, and may be connected through a bus bar or harness penetrating the SMD spacer 151. In a case where the SMD spacer 151 is used, the separate through hole 231 may not be formed.

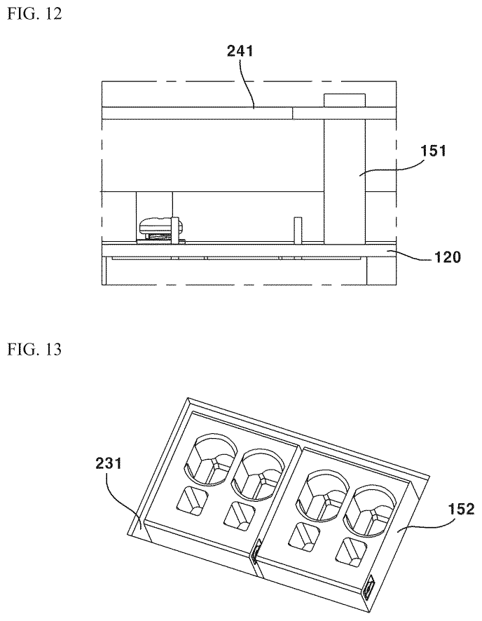

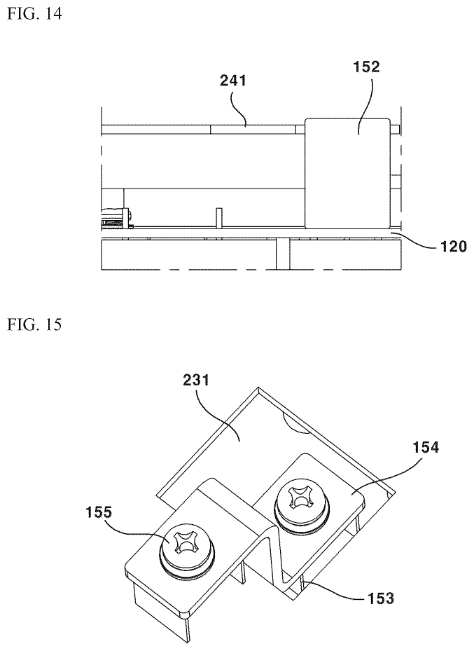

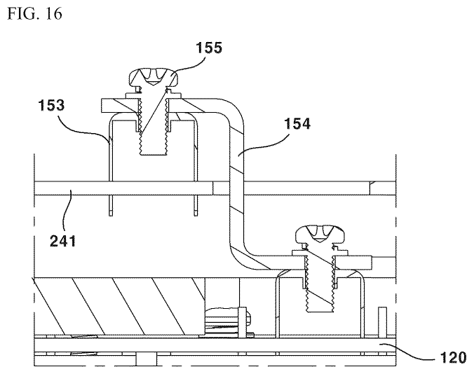

Alternatively, as shown in FIGS. 13 and 14, the first connector or the second connector may be formed with a wire connector 152. The wire connector 152 having a wire through-hole being formed therein may pass through the through-hole 231 of the heat sink 230, support the connection between the first substrate 120 and the main substrate 241, and may be connected through a wire penetrating the wire connector 152. Alternatively, as shown in FIGS. 15 and 16, the first connector or the second connector may be formed with a busbar terminal stand 153. The busbar terminal stands 153 may be disposed in the main substrate 241 and the first substrate 120, respectively, and the through-hole 231 of the heat sink 230 may pass through the bus bar 153 and be fixed with the screw 155.

In addition, the first substrate 120 and the main substrate 241, which are separate substrates, may be connected in various ways.

As described above, although the present invention has been described by specific matters such as specific components, limited embodiments, and drawings, these have been provided only to help a more general understanding of the present invention, and the present invention is not limited to the above embodiments, and those with common knowledge in the field to which the present invention belongs can make various modifications and variations from such descriptions.

Therefore, the spirit of the present invention should not be limited to the described embodiments, and not only the claims described below, but also all those with modifications equal to or equivalent to the claims will belong to the scope of this invention.

1-10. (canceled)

11. A capacitor module, comprising:
a housing comprising an accommodation groove in which a capacitor is disposed;
a substrate disposed above the accommodation groove; and
at least one capacitor mounted on one surface of the substrate and accommodated in the accommodation groove.

12. The capacitor module according to claim 11, wherein a plurality of first connectors electrically connected to the capacitors is disposed on other surface of the substrate.

13. The capacitor module according to claim 11, wherein the capacitor comprises a link capacitor.

14. The capacitor module according to claim 11, comprising a plurality of heat dissipation fins extended from an outer surface the accommodation groove.

15. The capacitor module according to claim 11, wherein the accommodation groove comprises:
a base;
a first side wall and a second side wall extended from the base and facing each other; and
a third side wall and a fourth side wall perpendicular to the first side wall and the second side wall and facing each other.

16. The capacitor module according to claim 11, wherein the accommodation groove comprises:
a first accommodation groove in which the capacitor is accommodated;
a second accommodation groove in which an inductor is disposed and spaced apart from the first accommodation groove; and
wherein at least one inductor is electrically connected to one surface of the substrate and accommodated in the second accommodation groove.

17. The capacitor module according to claim 16, wherein the second accommodation groove comprises:
a base; and
a fifth side wall extended from the base and having a circular shape.

18. The capacitor module according to claim 16, wherein the inductor comprises two inductors, and
wherein the two inductors are stacked in two layers in a depthwise direction of the second accommodation groove and connected to one surface of the substrate by a wire.

19. The capacitor module according to claim 16, wherein a plurality of second connectors electrically connected to the inductor is disposed on other surface of the substrate.

20. The capacitor module according to claim 11, wherein capacitor or inductor is molded into the accommodation groove.

21. An inverter module, comprising:
a first housing comprising a base comprising a first hole and having a main substrate disposed therein;
a cover covering the first housing;
a heat sink comprising a plurality of heat dissipation fins coupled to the first housing corresponding to the first hole and extended outward; and
a capacitor module disposed in a portion of an outer surface of the heat sink, wherein the capacitor module comprises:
a second housing comprising an accommodation groove in which a capacitor is disposed;
a first substrate disposed above the accommodation groove; and
at least one capacitor mounted on one surface of the first substrate and accommodated in the accommodation groove.

22. The inverter module according to claim 21, wherein a plurality of first connectors electrically connected to the capacitors is disposed on other surface of the first substrate.

23. The inverter module according to claim 22, wherein the heat sink comprises a through hole in a region corresponding to the plurality of first connectors.

24. The inverter module according to claim 23, wherein the plurality of first connectors passes through the through hole to be connected to the main substrate.

25. The inverter module according to claim 24, wherein the plurality of first connectors comprises at least one among an SMD spacer, a wire connector, and a busbar terminal stand.

26. The inverter module according to claim 21, wherein the main substrate comprises a first main substrate and a second main substrate stacked to be spaced apart from the first main substrate.

27. The inverter module according to claim 21, wherein the accommodation groove of the capacitor module comprises:
a first accommodation groove in which the capacitor is accommodated; and
a second accommodation groove in which an inductor is disposed and spaced apart from the first accommodation groove, and
wherein at least one inductor is electrically connected to one surface of the first substrate and accommodated in the second accommodation groove.

28. The inverter module according to claim 27, wherein the first inductor comprises two of the first inductors, and
wherein the two of first inductors are stacked in two layers in a depthwise direction of the second accommodation groove and connected to one surface of the first substrate by a wire.

29. The inverter module according to claim 21, comprising an inductor module disposed in other portion of an outer surface of the heat sink.

30. The inverter module according to claim 29, wherein the inductor module comprises:
a third housing comprising a third accommodation groove in which a second inductor is disposed; and
at least one second inductor accommodated in the third accommodation groove.
